(19) United States
(12) Patent Application Publication
(10) Pub. No.: US 2004/0087054 A1
(43) Pub. Date: May 6, 2004

(54) Disposable barrier technique for through wafer etching in MEMS

(75) Inventors: Jeffrey D. Chinn, Foster City, CA (US); Rolf A. Guenther, Monte Sereno, CA (US); Michael B. Rattner, Santa Clara, CA (US); James A. Cooper, San Jose, CA (US)

Correspondence Address: PATENT COUNSEL, APPLIED MATERIALS, INC., Legal Affairs Department, P.O.BOX 450A, Santa Clara, CA, 95052, US

(73) Assignee: Applied Materials, Inc.

(21) Appl. No.: 10/274,403

(22) Filed: Oct. 18, 2002

(51) Int. Cl. H01L 21/46; H01L 21/301; H01L 21/00; H01L 21/78

(52) U.S. Cl. 438/52

(57) ABSTRACT

Disclosed are methods of plasma etching through a substrate while preventing rapid leakage of heat transfer fluid during the etch process, protecting process chamber hardware underlying said substrate, and separating components within said substrate while maintaining said components in a position relative to other components within said substrate. The method involves application of a disposable protective barrier layer to the backside of the substrate prior to etching and then removing the barrier layer subsequent to etching.

### FIELD OF THE INVENTION

The present invention pertains to a method of using a disposable barrier layer in semiconductor fabrication and in Micro-Electro-Mechanical-Systems (MEMS) fabrication.

### BACKGROUND OF THE INVENTION

Recently, there has been great interest in miniature machines which combine electrical, optical and mechanical functional features. These micromachines are frequently referred to as Micro-Electro-Mechanical-Systems (MEMS). There are specialty MEMS in various technical fields, such as Bio-MEMS, and Micro-Opto-Electro-Mechanical-Systems (MOEMS). To provide economy of scale, MEMS devices may be prepared in multiplicity on a large substrate such as a semiconductor wafer using semiconductor processing techniques. Once the MEMS devices have been formed on the substrate, they need to be separated from the substrate as a whole into individual devices or structures. One means of separating the devices or structures is to leave sufficient space between devices on the substrate so that the substrate can be cut or diced into individual pieces.

FIG. 1A shows a wafer substrate containing a number of MEMS devices. FIG. 11B shows an enlargement of a portion of FIG. 1A which includes various components for a secondary electron detector MEMS, components such as an extractor 172, a spacer 174, a condenser 176, an anode 178, a blanker 180 and an aperture 182. In this particular instance, the MEMS devices are fabricated on the wafer to include sacrificial bridges 184 which can be diced, enabling separation of the devices from the substrate. The bridges 184 serve two purposes: to provide structural support within the silicon wafer and to provide a dicing lane. However, even when sacrificial bridges are provided, dicing of the substrate into individual MEMS devices may place considerable stress on the devices being separated. Also, mechanical dicing releases particles and particles may destroy the functionality of MEMS structures, as well as contaminate processing areas. Dicing may also be accomplished by cutting the wafer with a liquid jet stream, or a laser beam. However, the liquid in a liquid jet stream may affect the MEMS devices and the laser beam may cause heating which is detrimental.

One potential method for separating the substrate into various sections would be to completely etch through the substrate, using a wet etch process. However, a variety of MEMS devices are likely to be harmed by a wet etch process. Another method would be to etch through the substrate using a plasma dry etch.

When dry etching is used, to avoid damaging the pedestal underlying the substrate when the substrate is etched completely through, it is necessary to use a protective layer between the substrate and the pedestal. This protections is provided by a carrier which is designed to work in combination with the pedestal. Typically, the carrier is made of silicon carbide or aluminum. However, where the etching involves thru-wafer etching of features of varying dimensions, maintaining control over the etch as the etch breaks through the wafer is a real challenge. Due to etch micro-loading effects, larger areas etch faster than smaller features. In such instances, etch around the perimeter of larger areas would be complete while the etch around smaller areas is still in progress. Therefore, the surface of the silicon nitride or aluminum carrier underlying the larger area is exposed to the dry etch plasma. Etching of the carrier generates contamination which can damage MEMS structure.

It would be advantageous to have a method of separating the wafer substrate into individual devices without placing stress on the devices while preventing the release of particles.

### SUMMARY OF THE INVENTION

We have developed a method which permits separating of a MEMS device from a large substrate by etching completely through the substrate. The method provides support for the substrate while retaining the separated devices in position, without producing contamination and without damaging the underlying substrate support pedestal. This method involves applying a barrier layer to the backside of a substrate such as a wafer, and etching through the substrate up to the barrier layer. The barrier layer on the backside of the substrate is advantageously a tackified polymeric film or a polymeric film applied to the backside of the substrate using an adhesive. When an adhesive is used, it is particularly helpful when the adhesive can be irradiated to provide release of the barrier layer from the substrate. Presence of the barrier layer maintains the MEMS devices in relative position to each other after separation, and confines contaminants generated during the etch process upon the barrier layer.

The barrier layer may also be a layer of an inorganic material, so long as the inorganic material does not release contaminant materials when exposed to a plasma used to etch through the substrate. An example of an inorganic barrier layer material is silicon oxide.

The present invention also provides a method of controlling the coolant flow on the backside of a substrate such as a wafer during through etching. Since the barrier layer is in contact with a pedestal through which the cooling agent passes, the cooling agent is restrained between the barrier layer and the pedestal.

Another aspect of the invention involves a method of protecting process chamber etch hardware underlying a substrate by using a protective barrier layer under the substrate. Applying a barrier layer to the backside of the substrate protects hardware beneath the substrate from damage during the etch process and avoids the generation of particulates which can contaminate the etch processing chamber and elements within the chamber.

Another aspect of the invention involves a method of preventing contamination of an etch chamber by restraining contaminants generated during through etching of a substrate. The contaminants are restrained by a barrier layer beneath the substrate. Contaminants generated during etching are then discarded with the barrier layer when the barrier layer is released. In one embodiment, the contaminants are adhered to the barrier layer by an adhesive used to fasten the barrier layer to the substrate.

With respect to the use of an adhesive to fasten the barrier layer to the substrate, one embodiment of the method involves the use of an adhesive which is affected by irradiation in a manner which permits the easy release of the substrate from the barrier layer by irradiation of a surface of the barrier layer.

It is important to mention that, in terms of process integration, it is possible to carry out a plasma etch which simultaneously releases moving MEMS structures such as beams, levers, and gears, while etching through the substrate to separate individual devices.

### BRIEF DESCRIPTION OF THE DRAWINGS

The foregoing and other aspects of the invention will be appreciated in conjunction with the accompanying drawings, and a detailed description which follows.

FIG. 1A shows a top view of a silicon wafer 100 having MEMS devices present within the wafer.

FIG. 1B shows an enlargement of a portion of the etched silicon wafer 100 of FIG. 1A, showing details of the MEMS devices.

FIGS. 2A-2D illustrate the process of separating MEMS devices within a substrate by through etching of the substrate.

FIG. 2A shows a schematic of a cross section of a structure 220, which includes a wafer 227 that is prepared for patterned etching by applying a disposable barrier layer 230 to the backside 229 of the wafer and a patterned masking material 221 to the upper surface 210 of the wafer.

FIG. 2B shows a schematic of a cross section of a structure 220 having trenches 222, 224, 226 and 228 etched partially through the cross sectional thickness of wafer 227.

FIG. 2C shows a schematic of a cross section of the structure 220 of FIG. 2A, where the trenches are etched all the way through the wafer 227 thus separating the devices 232, 234, 236, 238, and 240 by trenches 228, 226, 224, and 222 respectively.

FIG. 2D shows a schematic of a cross section of structure 220 after the masking material 221 is removed from the upper surface 210 of the wafer 227.

FIGS. 3A-3C show a schematic of a cross-section of a wafer 300 mounted on an electrostatic chuck 304 which is present on the upper surface of a cathode 308. The electrostatic chuck 304 and cathode 308 have portals 306 through which a heat transfer fluid 307 passes during etch processing of the wafer 300.

FIG. 3A shows a schematic cross-section of a wafer 300 where the wafer is prepared for patterned etching, with a patterned masking material 320 on the upper surface 318 of the wafer 300.

FIG. 3B shows a schematic cross-section of the wafer 300 where smaller trenches 302 are partially etched through wafer 300, while large trench 303 is etched completely through wafer 300, with damage to electrostatic chuck 304 occurring due to the etch through.

FIG. 3C shows a schematic cross section of the wafer 300 where the wafer has become de-chucked from electrostatic chuck 304. This creates a gap 313 between the base 312 of wafer 300 and the upper surface of e-chuck 304 through which rapid and uncontrolled coolant fluid leakage 307 occurs.

FIGS. 4A-4D illustrate a method of preventing damage to an electrostatic chuck underlying wafer 300 when the wafer is etched through. These figures also illustrate a methods of preventing the rapid and uncontrolled escape of cooling fluid (gas) used for heat transfer during the etch process.

FIG. 4A shows a schematic cross-section of a wafer 400, where the wafer is prepared for patterned etching by applying a disposable barrier layer 408 to the backside 424 of the wafer; and, a hard masking material 420 with overlying patterned photoresist 407 on the upper surface 422 of the wafer.

FIG. 4B shows a schematic of a cross section of a semiconductor wafer 400 with the barrier layer 408 adhered to the backside of the wafer 400. The wafer 400 has smaller trenches 402 which are etched a portion of the way through the wafer t₁ thickness 414 and a large trench 403 which is etched completely through the wafer thickness 414.

FIG. 4C shows a schematic of a cross section of the semiconductor wafer 400 of FIG. 4B, where the etching is complete for all of the trenches, and progression of the etching is stopped by the barrier layer 408 having a t₂ thickness 413.

FIG. 4D shows a schematic of a cross section of the semiconductor wafer 400 after the etching is completed and the masking material 420 shown in FIG. 4C is removed from the upper surface 422 of the wafer 400.

FIGS. 5A and 5B are tracings made from photo micrographs which show cross-sectional views of a silicon wafer substrate 500 etched, using various etchant conditions, through a wafer thickness of about 600 μm.

FIG. 5A shows a photomicrograph cross-sectional view of an etched wafer 500 where the wafer thickness was 600 μm and the trench 507 width w₁ 503 was about 90 μm at the top 509 of the wafer 500 and the width w₂ 504 was about 160 μm at the base 510 of the wafer.

FIG. 5B shows a photomicrograph cross-sectional view of an etched wafer 500 where the wafer thickness was about 600 μm, the width w₃ 504 of large trenches 527 was about 90 μm at the top 529 of the wafer and width w₄ 524 was about 160 μm at the base 530 of the wafer. The width w₅ 525 of small trenches 528 was about 45 μm at the top 529 of the wafer and the width w₆ 526 was about 70 μm at the base 530 of the wafer.

FIG. 6 shows a tracing made from a photo micrograph cross sectional view of an etched wafer substrate 600 including a silicon portion 602 and a silicon oxide barrier layer 604 at the base 605 of wafer substrate 500.

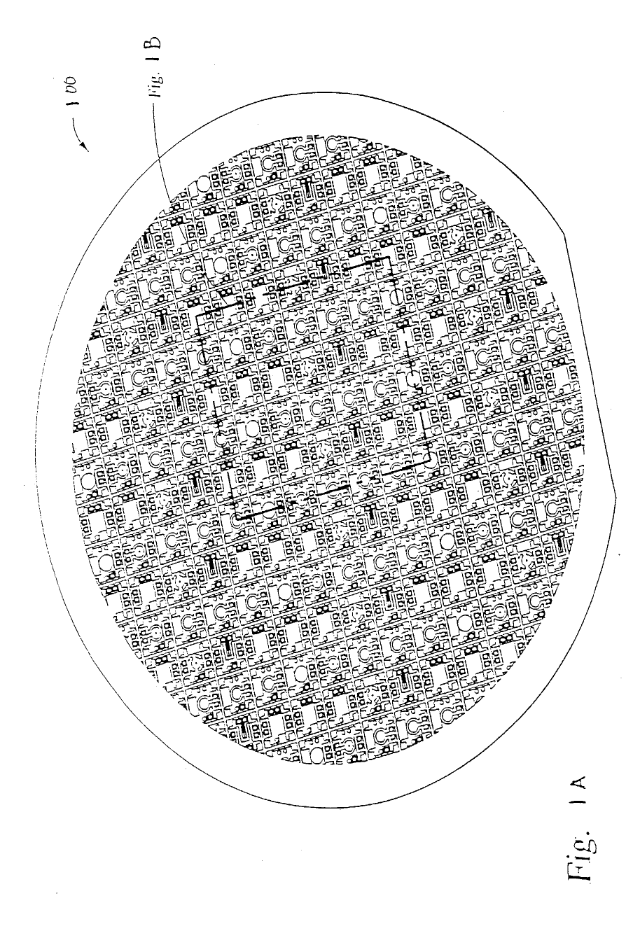

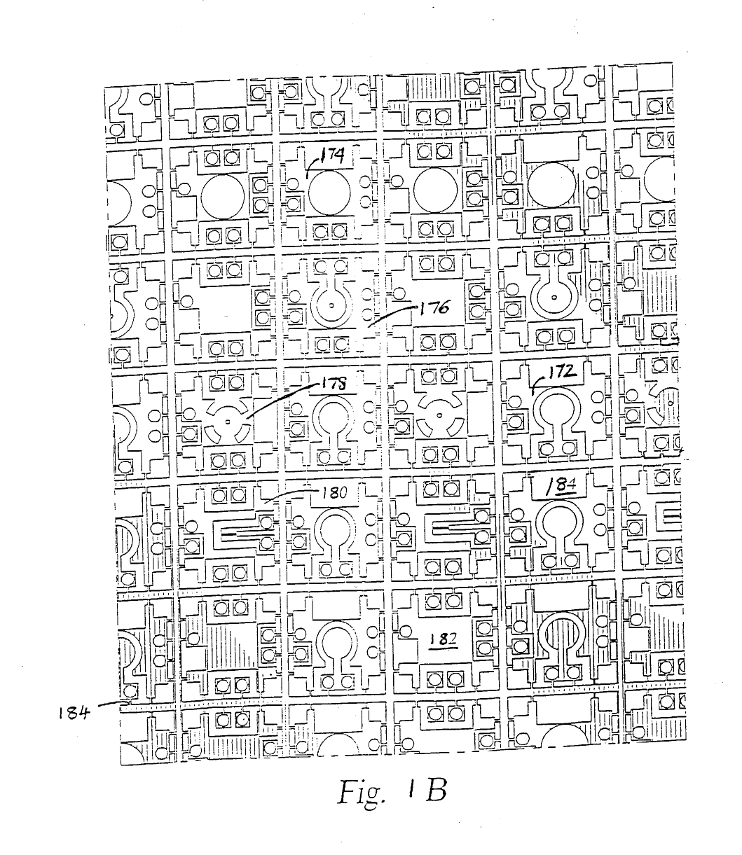

### DETAILED DESCRIPTION OF THE PREFERRED EMBODIMENT

We have developed a method of separating MEMS components within a substrate by through etching of the substrate. The substrate is prepared for patterned etching by applying a disposable barrier layer to the backside of the substrate and a patterned masking material on the top of the substrate. The masking material may be a patterned photoresist material, a patterned hard mask material (such as a metal oxide or a metal), or may be any suitable patterned material which possesses a different etch selectivity from the substrate underlying the mask. The substrate is plasma etched through the patterned mask, with the disposable barrier layer acting as an etch stop, as a carrier from which MEMS components are subsequently released, and as a retainer for contaminants generated during etching. (The barrier layer collects the residues from the etch process at the time of break through.) The barrier layer may be self adhered to the wafer, but is typically attached using a polymeric adhesive.

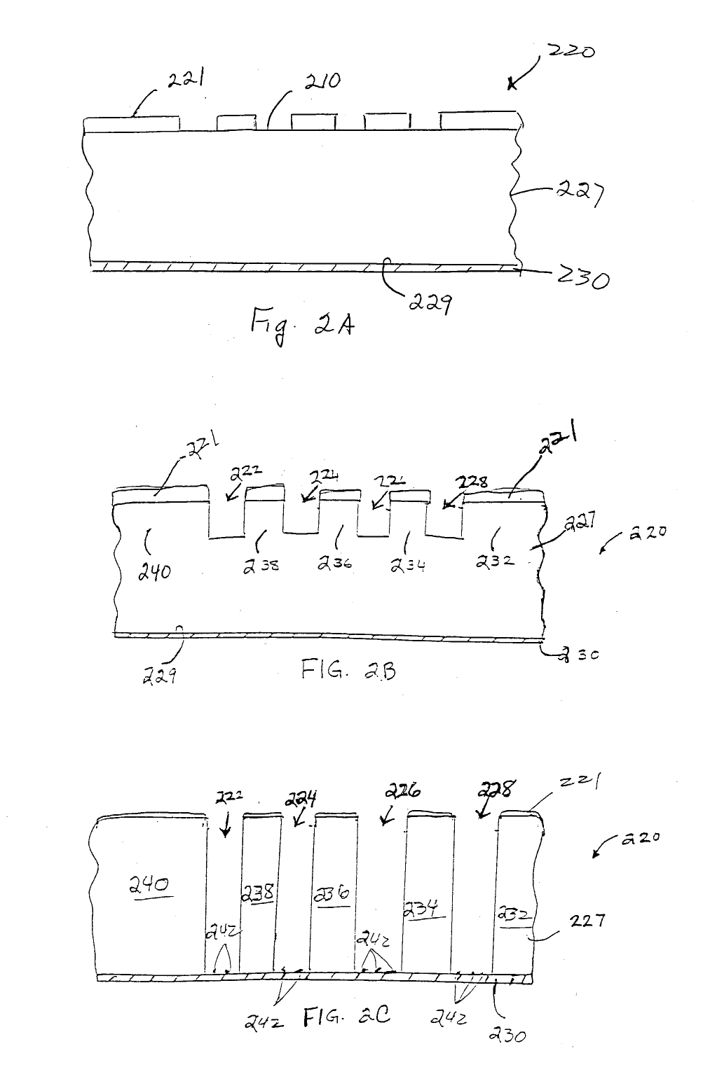

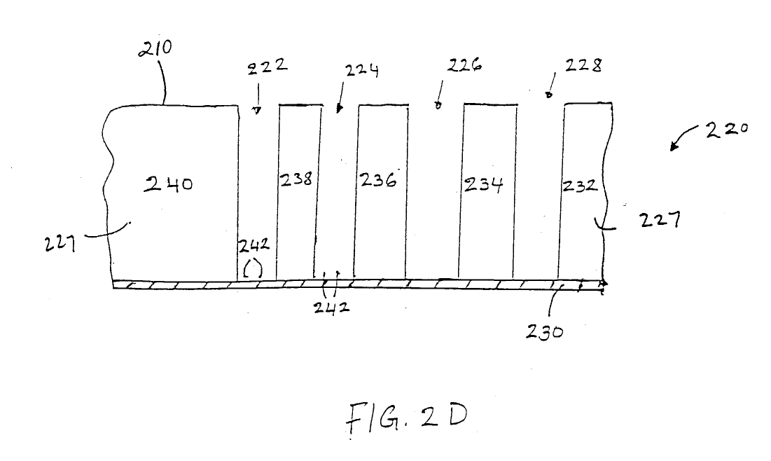

FIGS. 2A-2D show a schematic cross sectional view 220 of the progressive etching/separation of MEMS components present in a wafer 227. In FIG. 2A the wafer 227 is prepared for pattern etching by applying a disposable barrier layer 230 to the backside 229 of the wafer 227 using an adhesive (not shown) and a patterned masking layer 221 on the upper surface 210 of the wafer. FIG. 2B shows the wafer 227 as separating trenches are progressively etched around the MEMS components 240, 238, 236, 234 and 232 and into the wafer 227. In FIG. 2C, the etch proceeds all the way through the wafer 227 and is stopped by the barrier layer 230 which acts as an etch stop layer. As the etching is completed, the MEMS components 232, 234, 236, 238 and 240 are simultaneously separated from one another. The barrier layer 230 holds the MEMS components 232, 234, 236, 238 and 240 in place, preventing them from falling out of wafer 220. The barrier layer 230 also contains etch process residues 242 which might otherwise contaminate MEMS components 232, 234, 236, 238 and 240 or the etch processing chamber (not shown).

Once the etching is completed any residual masking material may be removed. The method of removing the masking material depends on the device and how the device would be affected by the method. One method for removal of masking material would be to dip the wafer in a chemical bath which would remove the masking material 221 and not the barrier layer 230. Another way to remove the masking material 221 would be by dry etching. Once the plasma etching to separate the MEMS components is completed, the plasma composition and/or processing conditions may be changed to accommodate mask residue removal. The etch selectivity of the plasma used for mask removal should be such that it selectively etches the masking material and not the MEMS components underlying the masking material, so that the masking material may be removed without affecting the MEMS components. Other methods for masking material removal, like ashing of a photoresist, may be employed when the devices can withstand the ashing conditions. FIG. 2D shows the etched wafer 227 after the residual masking material 221 has been removed.

Once the masking material is removed, the MEMS components may be released by exposing the adhesive (not shown) on barrier layer 230 to radiation (such as ultraviolet radiation) in order to reduce the adhesion of the barrier layer 230, permitting easy release of the components. As a result, the MEMS components 232, 234, 236, 238 and 240 fall right off barrier layer 230 in the absence of or under minimal application of force. Although not illustrated in FIGS. 2A-2C, one skilled in the art will recognize that in some instances, free moving MEMS elements such as lever arms and gears may be released by etching a sacrificial layer in the same etch process which is used to separate the MEMS devices within a wafer substrate.

The use of an adhered barrier layer during etching helps to hold all parts of the wafer in place while the MEMS components are separated. The barrier layer may also collect the particles generated during etching thus protecting the MEMS structures from particle contamination. The barrier layer may be adhered by a UV curable adhesive. The adhesive is plasma-resistant thus it can withstand long periods of exposure to plasma etch conditions without breaking down. The barrier layer is also plasma-resistant, permitting the use of a timed etch of the MEMS devices since the electrostatic chuck underlying the wafer is protected by the barrier layer. In cases where an etch end point detection is desired, depending on the properties of the adhesive and/or the barrier layer, and the etch chemistry, a unique hydrocarbon detection end point may be used as the adhesive and/or barrier layer are exposed to plasma. A color indication may also be included in the adhesive and/or barrier layer. The barrier layer (and adhesive if used) needs to have the capability of transferring heat between a cooling fluid underlying the barrier layer and the substrate overlying the barrier layer. A thermal conductivity of about 0.1 B.t.u./hr. ft. ° F. or greater ensures that thermal conductivity will at least meet minimal requirements.

Even though the invention as described above has been in terms of MEMS structures, the invention can be used in general semiconductor processing whenever plasma through-etching of a wafer is conducted.

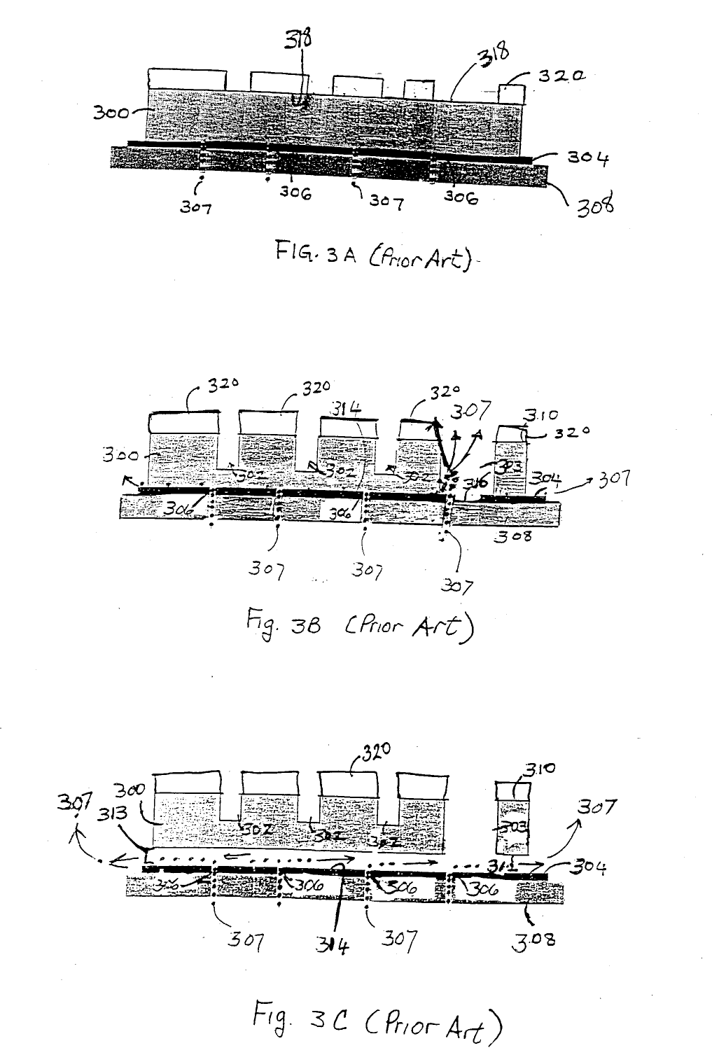

FIG. 3A shows a schematic cross-sectional view of a wafer 300, which has been prepared for patterned etching by application of a masking layer 320 on the upper surface 318 of the wafer 300. The wafer 300 is designed to be held in place on a cathode base 308 by the use of an electrostatic chuck 304. The cathode base 308 and electrostatic chuck 304 contain cooling ports 306 through which a cooling gas 307 passes (leaks) to cool the backside of wafer 300 during processing.

FIG. 3B shows a schematic cross-sectional view of a wafer 300 during patterned etching by a typical process of the kind described above. Here, narrow trenches 302 are partially etched through wafer 300 while a wide trench 303 is etched completely through wafer 300. When this occurs, there is damage to an exposed surface of electrostatic chuck 304 as shown at 316. If this occurs over a heat transfer fluid portal 306, cooling fluid 307 may escape in a rapid and uncontrolled manner, as illustrated in FIG. 3B.

Further, when wafer 300 is etched all the way through, as illustrated at trench 303, the electrostatic chuck may be damaged over a sufficient surface area of to eventually prevent adequate chucking of wafer 300. This may lead to floating of the wafer, as illustrated in FIG. 3C. When this happens, coolant gas 307 used for heat transfer between the backside 312 of the wafer 300 and the upper surface 314 of the electrostatic chuck 304 will escape at an uncontrolled rate into the process chamber (not shown). As a result, wafer 300 may overheat during the etch process and the etchant plasma gas supply will be contaminated by heat transfer gas 307. Even though a certain amount of leakage is necessary for heat transfer process, rapid leakage of the kind illustrated in FIG. 3C can lead to problems such as non-uniform cooling or pressure change during cooling.

One of the significant challenges which has deterred thru-wafer etching is maintaining control over the etch as the etch breaks through the wafer. Due to etch micro-loading effects, etched features having larger critical dimensions (larger etch areas) tend etch faster than smaller features. Dense and isolated features also tend to etch at different rates. Exposure of the etch hardware underlying the wafer to reactive chemistries of the plasma etch process for long periods is known to cause both wafer processing failures and etch apparatus damage. The present invention solves a number of such problems.

Applicants have developed a barrier layer which is applied to the back side of a substrate such as a wafer, to act as a etch stop which prevents damage to underlying hardware such as an electrostatic chuck surface. The barrier layer must be able to support the substrate, remain attached during plasma etching, act as a barrier layer to prevent the plasma from passing through to underlying hardware, permit heat transfer from a heat transfer fluid (such as a cooling fluid) into the substrate, and must not prevent the substrate from being chucked to an underlying electrostatic chuck (when such a chuck is used to support the substrate). Typically, the electrostatic chuck surface is a polymide layer which, if exposed to an etch plasma, would be etched away, gradually leading to electrostatic chuck failure. In cases where the electrostatic chuck used has a ceramic surface such as aluminum oxide, aluminum fluoride can build up and cause electrostatic chuck failure.

One possible barrier layer would be a thermal oxide layer on the backside of the wafer. However the thickness of a typical thermal oxide layer is between 2-3 microns. Due to the minimal thickness of such an oxide layer, when microloading effects are significant, it is likely that a breakdown in the oxide layer will occur due to etching through of the oxide layer. New techniques for creating thicker thermal oxide layers have been recently published, where a pattern is machined into a silicon surface so that upon oxidation the patterned area becomes a solid layer of silicon oxide. Use of a technique of this kind to produce a thicker silicon oxide layer may enable the use of a thermal oxide for this barrier layer application.

One barrier layer which works well is a polymeric barrier which is plasma resistant relative to a silicon substrate and which is capable of heat transfer. Examples of such polymeric barrier layer materials include PET (polyethylene terephthalate) and PO (Polyethylene oxide), by way of example and not by way of limitation. When a polymeric barrier layer is adhered to a substrate using a U.V. curable adhesive which is to be irradiated subsequent to etch processing, to release the barrier layer from the substrate, the polymeric barrier layer needs to be transparent to ultraviolet radiation.

### EXAMPLES:

### Example One

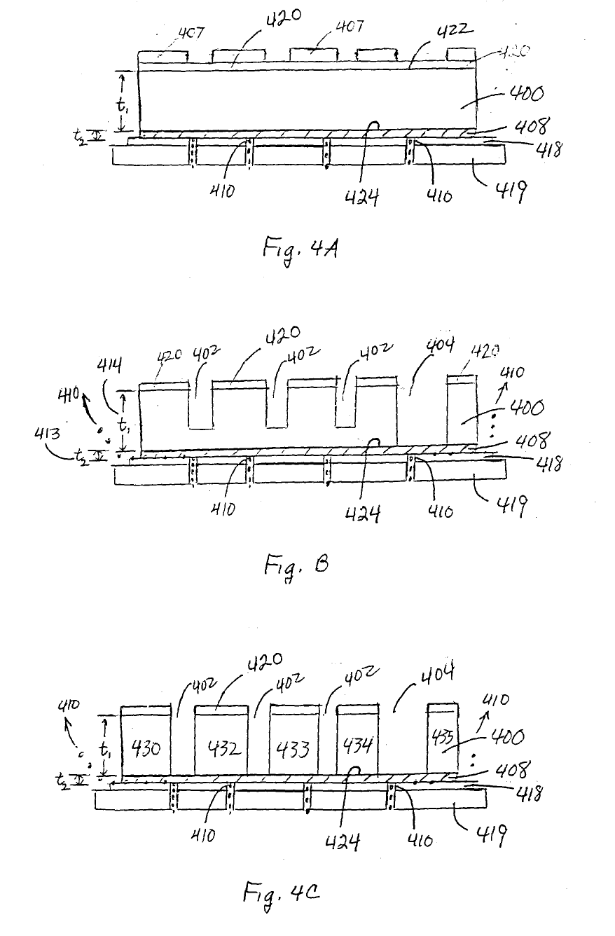

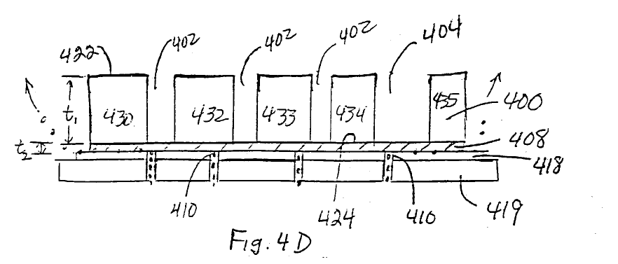

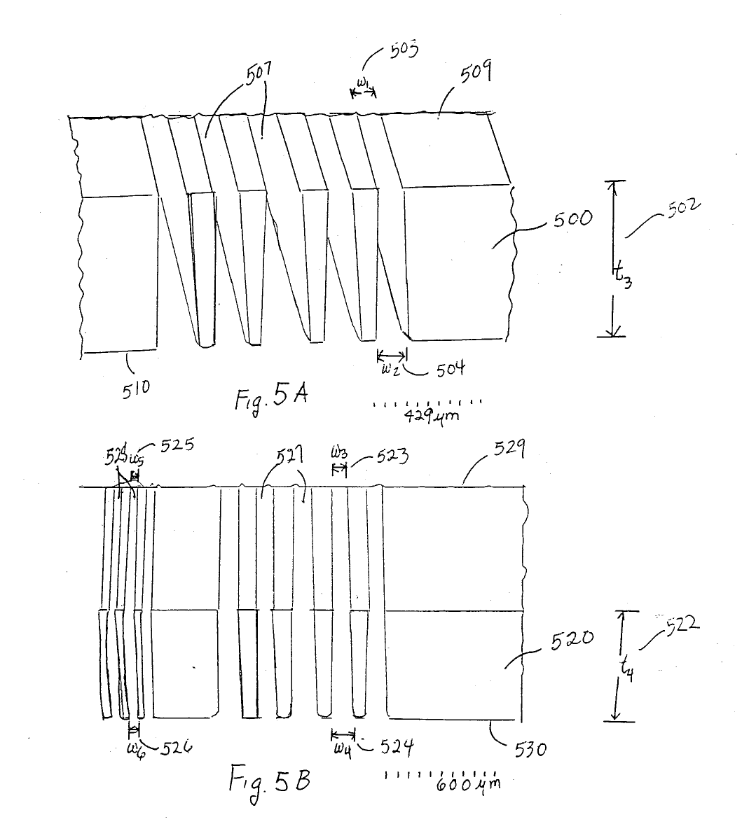

FIG. 4A shows a silicon wafer 400 which was prepared for patterned etching by applying a disposable barrier layer 408 adhered with a U.V. curable adhesive (not shown) to the backside 424 of the wafer 400. In addition a silicon oxide hardmask layer 420, with overlying patterned photoresist mask 407 was prepared on the upper surface 422 of the wafer 400. The photoresist was a standard “I”-line photoresist of the kind commonly used in the industry. This photoresist is a novolak-based photoresist.

There are a number of ultra-violet (UV), “curable”, adhesive tapes available on the market which may be used to provide a barrier layer. Generally, during backside grinding of a wafer and dicing of a wafer, an adhesive tape is applied to one of the sides of the wafer in order to firmly hold and support the wafer. Conventionally, the adhesive tapes are removed from the wafer after the grinding or dicing process, by heat treating or by exposing them to ultraviolet rays. UV curable tapes of such type may be used in this application so long as the tape fulfills the following criteria. The tape must adhere to the silicon substrate under semiconductor processing (in this instance etching) conditions, yet, it must be removable without the application of force that might harm the wafer. Also, the polymeric component of the tape must have sufficient selectivity with respect to the silicon substrate to act as an etch stop layer at a thickness which will permit heat transfer through the tape and permit electrostatic chucking of the silicon substrate through the tape. A polymeric tape component which is conductive or semiconductive is helpful in reducing charge build up during the plasma etch process.

We evaluated tapes GDSI-DT-UV-218 and GDSI-GT-UV-224, both manufactured by GDS, Inc. of Sunnyvale, Calif. and discovered that these tapes can perform under the plasma processing conditions described below. The GDSI-DT-UV-218 tape and the GDSI-GT-UV-224 are both polyethylene oxide films coated with a UV curable adhesive. The 218 tape has an adhesion prior to UV treatment of about 14.7 N/20 mm and an adhesion after UV treatment of about 0.2 N/20 mm. The 224 tape has an adhesion prior to UV treatment of about 2.9 N/20 mm and an adhesion after UV treatment of about 0.2 N/20 mm. The 218 tape is classified as an anti static tape, and we discovered that we had minimal to no charge build-up problems during plasma etching when this tape was used as the barrier layer. The thickness of the 218 tape is 175 μm and the thickness of the 224 tape is 110 μm. We found that both tapes permitted adequate heat transfer and permitted adequate e-chucking strength for the substrate. Both of these tapes are high temperature stability tapes. The glass transition temperature for the tapes is about 73° C., and the melting point is in the range of 250° C. Although the tapes became pliable at the typical substrate temperature during etch (which was maintained at less than about 130° C.) the tapes supported the substrate well at etch process conditions.

The silicon wafer 400 was supported and held in place upon the surface of an electrostatic chuck 418 atop a cathode 419 in a plasma processing chamber (not shown). E-chuck 418 and cathode 419 included a plurality of coolant ports 410 through which a heat transfer gas could be used to cool the backside 424 of wafer 400 during the etch process. The silicon wafer 400 thickness t₁ 414 was about 625 μm, and we used the 218 tape as a barrier layer, so the thickness t₂ 413 of the barrier layer was 175 μm. However, other thinner layers of barrier layer material are expected to work well, so long as there is sufficient selectivity for etching the silicon wafer preferentially relative to the barrier layer material. For example, a barrier layer having a thickness of about 70 μm should be adequate, so long as the selectivity for silicon:barrier layer is about 30:1 or greater. To etch through a silicon thickness of about 625 μm, required a cyclic etch process of the kind known in the art for etching silicon.

Generally, an etch process for etching through this thickness of silicon involves several cycles of deposition and etch. The deposition step prior to etching helps to protect the mask layer from being etched away and protects etched sidewalls as etching progresses, to provide a more vertical etch profile. We used a combination of a deposition cycle which employed C₄F₈ with an etch cycle which employed SF₆. Summaries of the process conditions are shown in Table 1 below. The table below shows three different etch cycles, where each cycle includes the steps of deposition and etch and repeating those steps for a certain number of times in order to etch to a certain depth into the wafer. The change in etch cycle as the etching progressed was used to achieve a desired etch profile. Generally, a vertical etch profile of 87° or better is preferred. As the etch proceeds further down in to the wafer, the required etch parameters differ in order to achieve a vertical etch profile of 87° or better. One skilled in the art can make further adjustments to optimize a given etch regimen.

TABLE 1
Process Conditions for Si Wafer Through Etch Using
an Adhesive Tape as a Barrier Layer

| | | Pres- | Plasma | Substrate | | | |
|---|---|---|---|---|---|---|---|
| | | sure | Source | Bias | Gas | | Repeat |
| | | (m- | Power Ws | Power Wb | Flow | Time | No. of |
| Cycle | Type | Torr) | (Watts) | (Watts) | (Sccm) | (see) | Times |
| 1 | dep | 70 | 1300 | 1 | 200 C₄F₈ | 5 | 200 |
| | etch | 70 | 1300 | 7 | 200 SF₆ | 6 | |
| 2 | dep | 70 | 1300 | 1 | 200 C₄F₈ | 5 | 100 |
| | etch | 70 | 1300 | 7 | 200 SF₆ | 7 | |
| 3 | dep | 70 | 1300 | 1 | 200 C₄F₈ | 5 | 100 |
| | etch | 70 | 1300 | 7 | 200 SF₆ | 8 | |

The substrate temperature during the etch process ranged from about 116° C. to about 120° C. We were particularly trying to maintain a substrate temperature below about 130° C. Substrate temperatures ranging from about 25° C. up to about 130° C. may be used, with concurrent adjustment of other process variables.

The back pressure on the cooling gas 410 was about 8 to 12 Torr.

The steps in cycle 1 included a deposition step for 5 seconds, followed by an etch step for 6 seconds. During cycle 1, the deposition and etch step cycles were repeated 200 times. The pressure throughout cycle 1 was maintained at 70 mT. The source power during deposition was 1300 W, while the bias power during deposition was typically about 1W. The source power during the etch step was about 1300W, while the bias power was increased to 7 kW. The plasma source gas used to generate the plasma during the deposition step was 200 sccm of C₄F₈ and the plasma source gas used to generate the plasma during the etch step is 200 sccm of SF₆. During cycle 1, the pattern in photoresist 407 was transferred through silicon oxide hard mask layer 420, to produce a patterned hard mask on the upper surface 422 of silicon wafer 400. In addition, the pattern was transferred through about 90 μm of silicon wafer beneath the hard mask. The etch rate averaged about 2-3 μm/min in the silicon wafer substrate 400, with the narrow trenches 402 etching at a rate which was about ⅔ of the etch rate for the wide trench 404.

The steps in cycle 2 included a deposition step for 5 seconds, followed by an etch step for 7 seconds. All other processing conditions remained constant. The cycle 2 deposition and etch steps cycles were repeated 100 times. During cycle 2, the etch rate averaged about 5-7 μm/min into the silicon wafer substrate 400, with the narrow trenches 402 continuing to etch at a slower rate than the wide trench 404.

The steps in cycle 3 included a deposition step for 5 seconds, followed by an etch step for 8 seconds. The cycle 3 deposition and etch steps cycles were repeated 100 times. All other processing conditions remained constant for the first 90 steps. During the last 10 steps, the flow rate of the SF₆ was increased about 10% to help shape the bottom of the trench and clean up the surface. During cycle 3, the etch rate averaged about 15-18 μm/min into the silicon wafer substrate 400. At the completion of etching of wide trench 404 all of the way through the wafer substrate 400, the narrow trenches 402 were etched about ⅔ of the way through the wafer substrate, as illustrated in FIG. 4B. Continued etching (overetching) is used to complete the etching of narrow trenches 402 completely through silicon wafer substrate 400, as shown in FIG. 4C, with the electrostatic chuck 418 is protected from the plasma by the barrier layer 408 of the GDSI-DT-UV-218 tape

Subsequent to the above Example One, we investigated the use of different substrate bias powers during the deposition and etch steps. A relatively low bias power can be used, because all that is needed is the generation of a conductive path to the cathode. As additional data was developed, it appeared that a substrate bias ranging between about 1W and about 20 W could be used, with a substrate bias ranging between about 4 W and about 15 W providing good results. We eventually set the substrate bias at about 10W during both the deposition and etch cycles.

Subsequent to the above Example One, we also investigated the use of different plasma source powers and determined that plasma source powers ranging from about 300 W to about 1,300 W could be used, with a plasma source power between about 300 W and about 800 W providing good results in terms of the profile of an etched trench. We determined that during cycle 1, where the hardmask opening takes place, it is advantageous to use a plasma source power between about 300 W and 500 W, in view of etch profile considerations.

FIG. 4C shows the time at which etch had proceeded all the way through the silicon wafer 400 and stopped at the disposable barrier layer 408. The disposable barrier layer 408 acts as an etch stop layer. The trenches 402 and 404 of FIG. 4C have now become gaps through the wafer. The disposable barrier layer 408 was of sufficient thickness and was etched with sufficient selectivity relative to the silicon wafer 400, that it prevented punch-through during etching. As a result, there is no rapid leakage of the coolant fluid 410 occurred during etch. The coolant typically used is helium, which makes a slow leak around the edges of wafer 400 as a part of the heat transfer process.

The disposable barrier layer 408 was of sufficient thickness, exhibited sufficient temperature stability (was stable at temperatures of at least 130° C.), and was etched with sufficient selectivity relative to the silicon wafer 400, that it was capable of supporting silicon wafer substrate 400 after the etching process. The silicon wafer 400 was then removed from the processing chamber with disposable barrier layer 408 attached.

The residual silicon oxide hard mask 420 which remained after etching was not removed during the Example One experimentation, but could easily be removed with minimal effect on the etched silicon wafer using a dry etch process of the kind known in the art. Typically such dry etch processes employ a plasma generated from a source gas containing chlorine and a fluorocarbon, by way of example and not by way of limitation. For etching silicon wafers having a thickness of about 200 μm or less in thickness, a patterned photoresist may be used in the absence of a hard mask. Residual photoresist is easily removed using oxygen-based ashing. This ashing process may be carried out in an ASP™ Chamber, or in an IPS™ chamber (typically used for oxide etching), both chambers available from Applied Materials, Inc. of Santa Clara, Calif. The method of removing the masking material depends on the MEMS device structure to be separated from the wafer, how the method will affect the device. Various methods for removing the masking material were previously discussed above.

The disposable barrier layer 408 was then easily removed by irradiation of the barrier layer with ultra violet light, to reduce the adhesion of the U.V. curable adhesive and to thereby release the MEMS components 430, 432, 433, 434, and 435 which are shown in FIGS. 4C and 4D. The use of an adhesive which can be irradiated with U.V. to permit a reduction in adhesive strength is recommended, as exposure of the wafer 400 to visible light (during handling) will not cause release of the barrier layer 408 from the silicon wafer 400. Since ultraviolet radiation decreases the adhesiveness of the barrier layer 408, release from the wafer 400 occurs without much force, and this reduces the wafer breakage or handling issues.

### Example Two

Depending on the device to be etched and the wafer thickness, trenches of varying sizes can be etched using the method of the invention. For example, a typical 8 inch wafer has a standard thickness of about 800 μm; a typical 6 inch wafer has a thickness of about 670 μm, and a typical 4 inch wafer, has a thickness of about 525 μm. Deep trenches from about 100 μm to about 800 μm can be etched with the use of a barrier layer of the kind described above in Example One. The barrier layer provides support for the silicon-wafer 400 and protects the underlying electrostatic chuck 418 during etching. As a result, it is not necessary to use another carrier for silicon wafer 400, simplifying the etch apparatus required. The typical thickness of the barrier layer ranges from about 80 μm to about 200 μm.

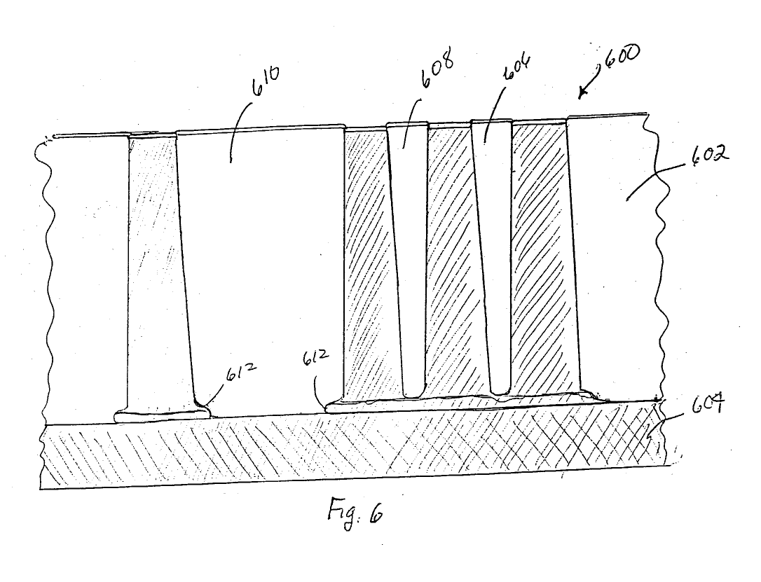

FIGS. 5A and 5B show tracings made from photomicrographs which illustrate a cross-sectional view of trenches etched using the method described above. We experienced some tapering of the etch profile with respect to the wider trenches and some bowing of the etch profile with respect to narrower trenches. However, by adjusting the cycles 1, 2, and 3 of the kind presented in Table 1, we were able to improve the profiles of the etched structures.

FIG. 5A shows a tracing of a photomicrograph illustrating a cross-sectional view of an etched wafer 500 where the wafer thickness was 600 μm and the trench 507 width w₁ 503 was about 90 μm at the top 509 of the wafer 500 and the width W₂ 504 was about 160 μm at the base 510 of the wafer. We were able to greatly reduce this etch profile taper by lengthening the etch step time in cycle 1 relative to the etch step times in cycles 2 and 3.

FIG. 5B shows a tracing of a photomicrograph illustrating a cross-sectional view of an etched wafer 500 where the wafer thickness was about 600 μm, the width w₃ 504 of large trenches 527 was about 90 μm at the top 529 of the wafer and width w₄ 524 was about 160 μm at the base 530 of the wafer. The width w₅ 525 of small trenches 528 was about 45 μm at the top 529 of the wafer and the width w₆ 526 was about 70 μm at the base 530 of the wafer. Again, the amount of taper was greatly reduced by adjusting the relative lengths of the etch steps among the etch cycles.

### Example Three (Comparative Example)

FIG. 6 shows a tracing made from a photo micrograph illustrating a cross sectional view of an etched wafer substrate 600 including a silicon portion 602 and a silicon oxide barrier layer 604 at the base 605 of wafer substrate 600. As can be seen from the photomicrograph, the use of a silicon oxide barrier layer affected the etch profile at the base of the silicon portion 602. A “notch” was produced at the base of wide trench 610. Although the notch was not observed for narrow trenches 606 and 608, these trenches had not yet reached the surface of silicon oxide barrier layer 604. Although we have limited data at this time, it appears the notching effect may be the result of charge build up in the area of the silicon oxide barrier layer. A comparison of FIGS. 5A and 5B with FIG. 6 clearly illustrates that there is a definite advantage in etch profile when using the an anti-static barrier layer of the kind described with respect to Example One. Other barrier layers which are even more conductive than the anti-static tape are expected to provide an advantage in the avoidance of charge build up which affects etch profile.

The use of a polymeric barrier layer of the kind described above in Example One was compatible with the etch chamber. No contaminant build-up was observed upon completion of etching. It appeared that some etch residues were collected on the barrier layer.

The above described preferred embodiments are not intended to limit the scope of the present invention, as one skilled in the art can, in view of the present disclosure, expand such embodiments to correspond with the subject matter of the invention claimed below.

What is claimed is:

1. A method of separating MEMS devices within a substrate by etching through the substrate, comprising:
(a) applying a polymer-comprising barrier layer to a surface of a substrate; and
(b) plasma etching through said substrate up to said polymer-comprising barrier layer.

2. A method as recited in claim 1, wherein said substrate is a semiconductor substrate.

3. A method as recited in claim 1, wherein said polymer-comprising barrier layer is sufficiently stable to support said substrate up to a temperature of about 130° C. or less.

4. A method as recited in claim 1, wherein said polymer-comprising barrier layer is adhered to said substrate surface by an adhesive which can be irradiated with ultra violet radiation to reduce the adhesion of said barrier layer to said substrate.

5. A method as recited in claim 1, or claim 2, or claim 3, or claim 4, wherein said polymer-comprising barrier layer has anti-static properties.

6. A method as recited in claim 1 or claim 3 or claim 4, wherein said barrier layer exhibits a thermal conductivity of about 0.1 B.t.u./hr. ft. ° F. or greater.

7. A method as recited in claim 1, or claim 2, or claim 3, or claim 4, wherein said barrier layer thickness ranges from about 80 μm to about 200 μm.

8. A method as recited in claim 1, or claim 2, or claim 3, or claim 4, including an additional step: (c) removing said barrier layer.

9. A method as recited in claim 4, including an additional step: (c) removing said barrier layer, wherein said barrier layer removal includes the irradiation of said barrier layer with ultra violet radiation.

10. A method of controlling the flow of heat transfer fluid during plasma etching through a substrate, comprising:
(a) applying a barrier layer to a surface of a substrate; and
(b) etching through said substrate up to said barrier layer.

11. A method as recited in claim 10, wherein said substrate is a semiconductor substrate.

12. A method as recited in claim 10, wherein said polymer-comprising barrier layer is stable at temperatures up to about 130° C.

13. A method as recited in claim 10, wherein said polymer-comprising barrier layer is adhered to said substrate surface by an adhesive which can be irradiated with ultra violet radiation to reduce the adhesion of said barrier layer to said substrate.

14. A method as recited in claim 10, or claim 11 or claim 12, or claim 13, wherein said polymer-comprising barrier layer has anti-static properties.

15. A method as recited in claim 10 or claim 11 or claim 13, wherein said barrier layer exhibits a thermal conductivity of about 0.1 B.t.u./hr. ft. ° F. or greater.

16. A method as recited in claim 10, or claim 11 or claim 12, or claim 13, wherein said barrier layer thickness ranges from about 80 μm to about 200 μm.

17. A method of protecting an electrostatic chuck during plasma etching, comprising:
(a) applying a polymer-comprising barrier layer to a surface of a substrate to be etched, which surface is in contact with said electrostatic chuck; and
(b) plasma etching through said substrate up to said polymer-comprising barrier layer.

18. A method as recited in claim 17, wherein said substrate is a semiconductor substrate.

19. A method as recited in claim 17, wherein said polymer-comprising barrier layer is stable at temperatures up to about 130° C.

20. A method as recited in claim 17, wherein said polymer-comprising barrier layer is adhered to said substrate surface by an adhesive which can be irradiated with ultra violet radiation to reduce the adhesion of said barrier layer to said substrate.

21. A method as recited in claim 17, or claim 18 or claim 19, or claim 20, wherein said polymer-comprising barrier layer has anti-static properties.

22. A method as recited in claim 17 or claim 18 or claim 19, or claim 20, wherein said barrier layer exhibits a thermal conductivity of about 0.1 B.t.u./hr. ft. ° F. or greater.

23. A method as recited in claim 17, or claim 18 or claim 19 or claim 20, wherein said barrier layer thickness ranges from about 80 μm to about 200 μm.

24. A method of preventing contamination of an etch chamber by introduction of etch process byproducts, comprising:
(a) applying a polymer-comprising barrier layer to a surface of a substrate to be etched, which surface is in contact with said electrostatic chuck; and
(b) plasma etching through said substrate up to said polymer-comprising barrier layer.

25. A method as recited in claim 24, wherein said substrate is a semiconductor substrate.

26. A method as recited in claim 24, wherein said polymer-comprising barrier layer is stable up to temperatures of about 130 C.

27. A method as recited in claim 24, wherein said polymer-comprising barrier layer is adhered to said substrate surface by an adhesive which can be irradiated with ultra violet radiation to reduce the adhesion of said barrier layer to said substrate.

28. A method as recited in claim 24, or claim 25 or claim 26 or claim 27, wherein said barrier layer thickness ranges from about 80 μm to about 200 μm.
